(19) United States
(12) Patent Application Publication
(10) Pub. No.: US 2012/0138982 A1
(43) Pub. Date: Jun. 7, 2012

(54) LIGHT-EMITTING DIODE DEVICE

(75) Inventors: Kuanqun Chen, Tainan City (TW); Changhsin Chu, Tainan City (TW); Kuohui Yu, Tainan City (TW)

(73) Assignee: CHI MEI LIGHTING TECHNOLOGY CORP., Tainan City (TW)

(21) Appl. No.: 13/081,741

(22) Filed: Apr. 7, 2011

(30) Foreign Application Priority Data
Dec. 7, 2010 (TW) 099142641

(51) Int. Cl. H01L 33/60

(52) U.S. Cl. 257/98; 257/E33.072

(57) ABSTRACT

A light-emitting diode (LED) device. In one embodiment, the LED device includes a heat dissipation bulk, a first electrode pad, a second electrode pad and at least one LED chip. The heat dissipation bulk includes at least two concaves. The first electrode pad and the second electrode pad are respectively disposed in the concaves and are electrically isolated from each other. The LED chip is embedded into the heat dissipation bulk, and the heat dissipation bulk electrically isolates the LED chip, the first electrode pad and the second electrode pad. The LED chip includes a first electrode and a second electrode of different conductivity types, and the first electrode and the second electrode are electrically connected to the first electrode pad and the second electrode pad respectively.

### CROSS-REFERENCE TO RELATED APPLICATIONS

This non-provisional application claims priority under 35 U.S.C. §119(a) on Patent Application No. 099142641 filed in Taiwan, R.O.C. on Dec. 7, 2010, the entire contents of which are hereby incorporated by reference.

### FIELD OF THE INVENTION

The present invention relates to a light-emitting device, and more particularly to a light-emitting diode (LED) device.

### BACKGROUND OF THE INVENTION

Along with the increasing demands for the application of LEDs in high luminous products like illuminators and headlights of vehicles, the operating power of the LED chip must be increased accordingly. However, generally, about 80% of the input power of an LED chip is transformed into heat and only 20% is transformed into light. Therefore, the heat generated by the high power LED chip is greatly increased, thus causing the dramatic increase of the heat dissipation demands of the LED chip.

FIG. 1 is a sectional view of a conventional LED device. The LED device 100 includes a metal heat dissipation bulk 102, a reflective layer 104, a metal adhesion layer 106, an LED chip 108, two electrode pads 124, 130, and two bonding wires 136, 138.

The reflective layer 104 is disposed on the metal heat dissipation bulk 102. The LED chip 108 is disposed on the reflective layer 104 through the metal adhesion layer 106. The LED chip 108 generally includes a substrate 110, an n-type semiconductor layer 112, an active layer (light emitting layer) 114, a p-type semiconductor layer 116, an n-type electrode 118 and a p-type electrode 120. The n-type semiconductor layer 112 covers the substrate 110. The active layer 114 is disposed on a part of the n-type semiconductor layer 112 and exposes the other part of the n-type semiconductor layer 112. The p-type semiconductor layer 116 covers the n-type semiconductor layer 112. The n-type electrode 118 is disposed on the exposed part of the n-type semiconductor layer 112. The p-type electrode 120 is disposed on a part of the p-type semiconductor layer 116. As influenced by the manufacturing process, a major part of the substrate 110 of the LED chip 108 is embedded into the metal adhesion layer 106, as shown in FIG. 1.

The electrode pads 124, 130 are both disposed on the metal adhesion layer 106 through an adhesion layer 122. The electrode pads 124, 130 are respectively disposed on two sides of the LED chip 108. The electrode pad 124 includes an insulating layer 126 and a conductive layer 128 disposed in sequence on the adhesion layer 122. The insulating layer 126 is used to electrically isolate the conductive layer 128 and the metal adhesion layer 106. On the other hand, the electrode pad 130 includes an insulating layer 132 and a conductive layer 134 disposed in sequence on the adhesion layer 122. Likewise, the insulating layer 132 is used to electrically isolate the conductive layer 134 and the metal adhesion layer 106. The electrode pad 124 and the p-type electrode 120 may be electrically connected and the electrode pad 130 and the n-type electrode 118 may be electrically connected through the bonding wires 136, 138 respectively.

In the LED device 100, since a major part of the LED chip 108 is embedded in the metal adhesion layer 106, the heat generated by the LED chip 108 in operation may be conducted to the lower metal heat dissipation bulk 102 through the metal adhesion layer 106 and the reflective layer 104, and further dissipated to the outside through the metal heat dissipation bulk 102. Therefore, this design of the LED device 100 is beneficial to improving the heat dissipation of the LED chip 108.

In the LED device 100, the active layer 114 of the LED chip 108 is not embedded into the metal adhesion layer 106. However, as the side edges of the substrate 110 are mostly wrapped by the metal adhesion layer 106 and the metal adhesion layer 106 has the opaque characteristic, most of the light emitted by the active layer 114 towards the substrate 110 is confined in the LED chip 108. For example, the light may be reflected multiple times in the substrate 110. Thus, the light cannot be successfully emitted out of the LED chip 108, which greatly reduces the luminous efficiency of the LED device 100.

Furthermore, the electrode pads 124, 130 both protrude from a surface of the metal adhesion layer 106. As a result, the electrode pads 124, 130 block the side light emitted by the active layer 114 of the LED chip 108 and the overall luminance of the LED device 100 is reduced.

Therefore, a heretofore unaddressed need exists in the art to address the aforementioned deficiencies and inadequacies.

### SUMMARY OF THE INVENTION

Accordingly, in one aspect, the present invention is directed to an LED device. In one embodiment, electrode pads may be partially or completely embedded into the heat dissipation bulk, so that the influence of the electrode pads on the side light emitted by the LED chip can be avoided or reduced. Therefore, the overall luminance of the LED device can be effectively improved.

In another aspect, the present invention is directed to an LED device. In one embodiment, a substrate of the LED chip is partially embedded into the heat dissipation bulk, so that the heat generated by the LED chip in operation can be directly conducted downwards to the heat dissipation bulk, thus rapidly dissipating the heat generated in operation. Therefore, the operating quality of the LED device can be improved and the service life of the LED device can be extended.

In yet another aspect, the present invention is directed to an LED device. In one embodiment, a depth of the substrate of the LED chip embedded into the heat dissipation bulk is controlled, so that the light emitted by the LED chip towards the substrate can be reflected by the heat dissipation bulk to the outside of the LED device through the light transmissive substrate. Therefore, the overall luminance of the LED device can be further improved.

In one aspect of the present invention, an LED device is provided. The LED device includes a heat dissipation bulk, a first electrode pad, a second electrode pad and at least one LED chip. The heat dissipation bulk includes at least two concaves. The first electrode pad and the second electrode pad are respectively disposed in the concaves and are electrically isolated from each other. The LED chip is embedded into the heat dissipation bulk, and the heat dissipation bulk electrically isolates the LED chip, the first electrode pad and the second electrode pad. The LED chip includes a first electrode and a second electrode of different conductivity types, and the first electrode and the second electrode are electrically connected to the first electrode pad and the second electrode pad respectively.

In one embodiment, the heat dissipation bulk includes a metal bulk and a ceramic layer. The ceramic layer is disposed on the metal bulk, and electrically isolates the first electrode pad, the second electrode pad and the LED chip.

In another embodiment, the heat dissipation bulk further includes a reflective layer disposed between the metal bulk and the LED chip.

In yet another embodiment, the ceramic layer conformally covers a surface of the metal bulk. Furthermore, the heat dissipation bulk further includes a reflective layer conformally covering the surface of the metal bulk and disposed between the metal bulk and the ceramic layer.

In a further embodiment, the ceramic layer covers an inner side surface and a bottom surface of each of the concaves.

In another aspect of the present invention, an LED device is further provided. The LED device includes a heat dissipation bulk, at least one electrode pad and at least one LED chip. The heat dissipation bulk includes at least one concave. The electrode pad is disposed in the concave. The LED chip is embedded into the heat dissipation bulk, and the heat dissipation bulk electrically isolates the LED chip and the electrode pad. The LED chip includes a first electrode embedded into the heat dissipation bulk and a second electrode disposed on the other side of the LED chip opposite to the first electrode. The second electrode is electrically connected to the electrode pad through at least one bonding wire, and the first electrode and the heat dissipation bulk are electrically connected.

In one embodiment, the heat dissipation bulk includes a metal bulk and a ceramic layer. The ceramic layer is disposed on the metal bulk, and electrically isolates the electrode pad and the LED chip.

In another embodiment, the LED chip includes an active layer. The electrode pad partially protrudes from the heat dissipation bulk and is lower than the active layer.

In yet another embodiment, the electrode pad is completely embedded into the concave.

In a further embodiment, a ratio of a thickness of the LED chip to a depth of the LED chip embedded into the heat dissipation bulk is between 10 and 15.

By partially or completely embedding the electrode pads into the heat dissipation bulk, the blockage of the side light emitted by the LED chip by the electrode pads can be avoided or reduced, thus effectively improving the overall luminance of the LED device. Furthermore, by partially embedding the substrate of the LED chip into the heat dissipation bulk, the heat generated by the LED chip in operation can be directly conducted downwards to the heat dissipation bulk, thus improving the operating quality of the LED device and extending the service life of the LED device.

In addition, by controlling the depth of the substrate of the LED chip embedded into the heat dissipation bulk, the tight confinement of the light emitted by the LED chip towards the substrate can be avoided. Thus the light emitted towards this direction can still be emitted to the outside, which further improves the overall luminance of the LED device.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a sectional view of a conventional LED device;

FIG. 2 is a sectional view of an LED device according to one embodiment of the present invention;

FIG. 3 is a sectional view of an LED device according to another embodiment of the present invention; and

FIG. 4 is a sectional view of an LED device according to yet another embodiment of the present invention.

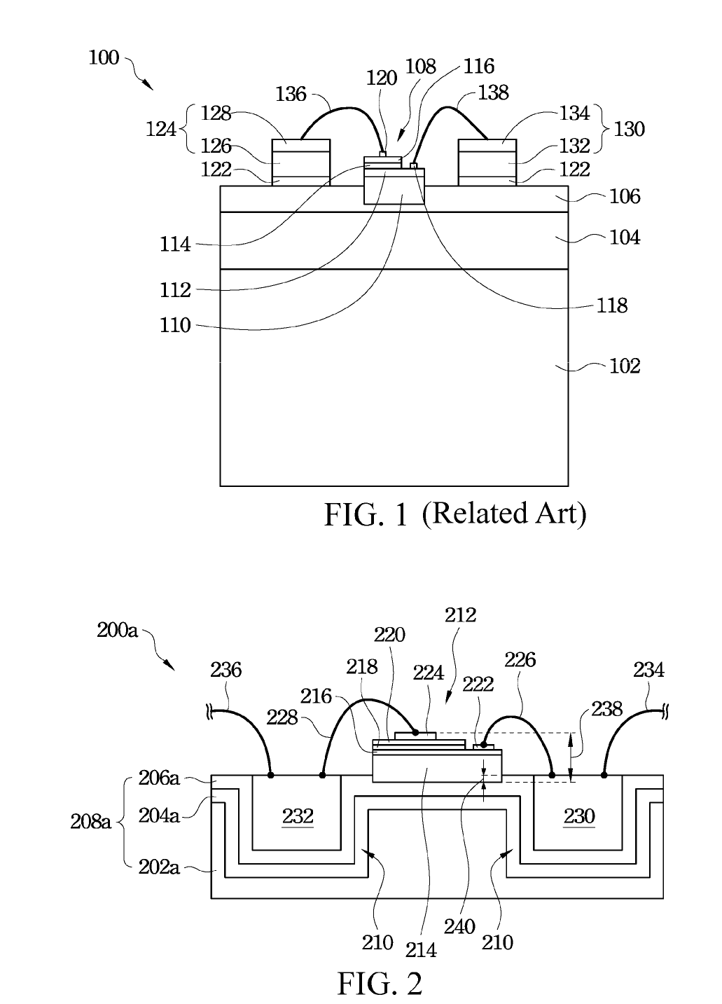

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

FIG. 2 is a sectional view of an LED device according to one embodiment of the present invention. In this embodiment, the LED device 200a includes a heat dissipation bulk 208a, at least one LED chip 212 and electrode pads 230, 232. The LED chip 212 is disposed on the heat dissipation bulk 208a, and the electrode pads 230, 232 are embedded into the heat dissipation bulk 208a.

The heat dissipation bulk 208a may be provided with one or more concaves for the electrode pads to be disposed therein. In this embodiment, the number of the concaves of the heat dissipation bulk 208a is the same as that of the electrode pads of the LED device 200a. Therefore, in the embodiment of FIG. 2, the heat dissipation bulk 208a may include two concaves 210 for respectively accommodating the electrode pads 230, 232.

In the embodiment, as shown in FIG. 2, the heat dissipation bulk 208a, for example, may include a metal bulk 202a, a reflective layer 204a and a ceramic layer 206a. The reflective layer 204a conformally covers a surface of the metal bulk 202a. The ceramic layer 206a conformally covers the reflective layer 204a, so that the reflective layer 204a is disposed between the metal bulk 202a and the ceramic layer 206a. The ceramic layer 206a has an insulating characteristic and may electrically isolate the electrode pads 230, 232 in the heat dissipation bulk 208a and the LED chip 212 disposed on the heat dissipation bulk 208a. The reflective layer 204a is between the LED chip 212 and the metal bulk 202a, and thus can reflect the light emitted by the LED chip 212 towards the heat dissipation bulk 208a.

In another embodiment, when the material of the metal bulk 202a is a highly reflective metal, the reflective layer 204a can be omitted. That is, the ceramic layer 206a directly conformally covers the surface of the metal bulk 202a.

The material of metal bulk 202a is preferably a high thermal conductivity material. In an embodiment, the material of the metal bulk 202a comprises, for example, Cu, Cu alloy, Fe/Ni alloy, Ni, W, Mo or any combination thereof. The material of the reflective layer 204a may be, for example, a stack structure of Ag/Au. The ceramic layer 206a may be preferably a transparent material, e.g. Al₂O₃.

In this embodiment, the LED chip 212 is of a horizontal conductive type. The LED chip 212 mainly includes a substrate 214, a first conductivity type semiconductor layer 216, an active layer 218, a second conductivity type semiconductor layer 220, a first electrode 222 and a second electrode 224. The first conductivity type semiconductor layer 216 and the second conductivity type semiconductor layer 220 are of different conductivity types. For example, one of the first conductivity type semiconductor layer 216 and the second conductivity type semiconductor layer 220 is n-type and the other is p-type. Furthermore, the first electrode 222 and the first conductivity type semiconductor layer 216 are of the same conductivity type, and the second electrode 224 and the second conductivity type semiconductor layer 220 are of the same conductivity type.

The substrate 214 is preferably a transparent substrate, e.g., a sapphire substrate. The first conductivity type semiconductor layer 216 is disposed on the substrate 214. The active layer 218 is disposed on a part of the first conductivity type semiconductor layer 216 and exposes the other part of the first conductivity type semiconductor layer 216. The second conductivity type semiconductor layer 220 is disposed on the active layer 218. The first electrode 222 is disposed on the exposed part of the first conductivity type semiconductor layer 216. The second electrode 224 is disposed on a part of the second conductivity type semiconductor layer 220. The first electrode 222 and the second electrode 224 are at least electrically connected to the electrode pads 230, 232 respectively through bonding wires 226, 228. The electrode pads 230, 232 are connected to an external power source respectively through bonding wires 234, 236.

In one embodiment, the LED device 200a may only include a single LED chip 212. In another embodiment, the LED device 200a may include multiple LED chips 212. In this embodiment, each LED chip 212 needs to be used in combination with two electrode pads. Therefore, the number of the electrode pads may be adjusted in accordance with the number of the LED chips 212 of the LED device 200a.

As shown in FIG. 2, a part of the substrate 214 of the LED chip 212 is embedded into the heat dissipation bulk 208a. In this embodiment, a depth 240 of the LED chip 212 embedded into the heat dissipation bulk 208a is controlled to prevent the light emitted by the active layer 218 of the LED chip 212 towards the heat dissipation bulk 208a from being excessively confined by the heat dissipation bulk 208a. In one embodiment, when the thickness 238 of the LED chip 212 is 150 μm, the depth 240 of the LED chip 212 embedded into the heat dissipation bulk 208a may be between 6 μm and 10 μm, the thickness of the substrate 214 may be, for example, between 140 μm and 145 μm, and the thickness of the heat dissipation bulk 208a may be, for example, 200 μm.

In a preferred embodiment, the ratio of the thickness 238 of the LED chip 212 to the depth 240 of the LED chip 212 embedded into the heat dissipation bulk 208a may be, for example, between 10 and 15.

In one embodiment, as shown in FIG. 2, the electrode pads 230, 232 may both be completely embedded into the concaves 210. In another embodiment, the electrode pads 230, 232 may be partially embedded into the concaves 210, and partially protrude from the heat dissipation bulk 208a. In this embodiment, the parts of the electrode pads 230, 232 protruding from the heat dissipation bulk 208a are preferably lower than the active layer 218 of the LED chip 212. The height of the electrode pads 230, 232 protruding from the heat dissipation bulk 208a may be, for example, between 0 μm and 100 μm.

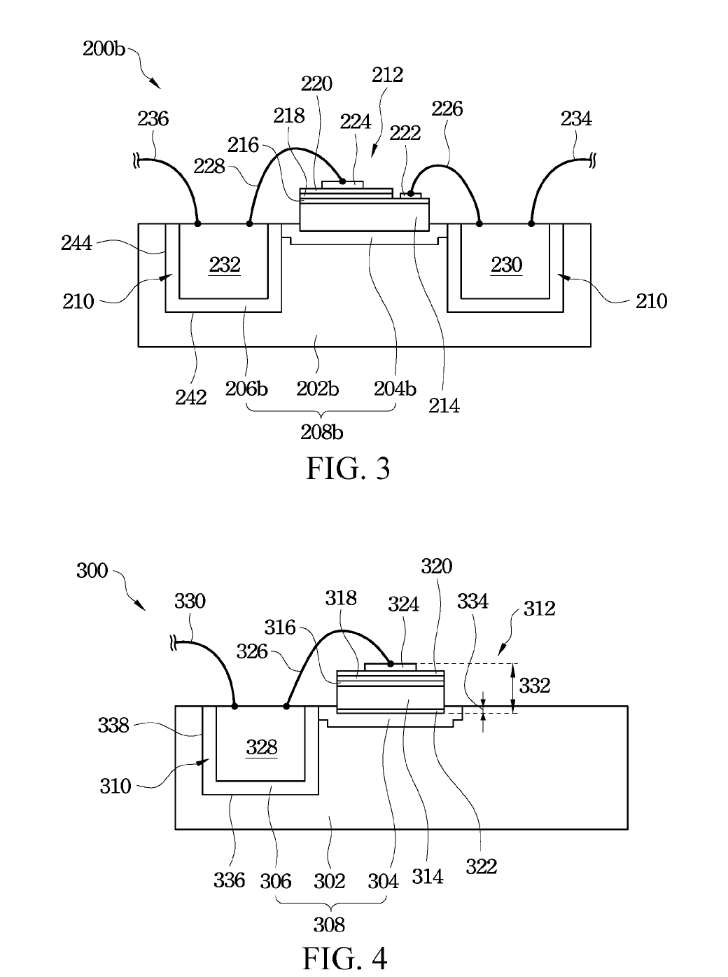

The heat dissipation bulk of the LED device may have other type of designs. FIG. 3 is a sectional view of an LED device according to another embodiment of the present invention. In this embodiment, the architecture of the LED device 200b is substantially the same as that of the LED device 200a in FIG. 2, and the difference of the two lies in that the architecture of the heat dissipation bulk 208b of the LED device 200b is different from that of the heat dissipation bulk 208a of the LED device 200a.

In the LED device 200b, the heat dissipation bulk 208b may also include a metal bulk 202b, a reflective layer 204b and a ceramic layer 206b. Different from the heat dissipation bulk 208a, the reflective layer 204b and the ceramic layer 206b of the heat dissipation bulk 208b do not conformally cover the metal bulk 202b and also do not cover the entire upper surface of the metal bulk 202b. The ceramic layer 206b covers a bottom surface 242 and an inner side surface 244 of each of the concaves 210. The electrode pads 230, 232 are disposed inside the ceramic layer 206b in the concaves 210. As a result, the insulative ceramic layer 206b of the heat dissipation bulk 208b electrically isolates the electrode pads 230, 232 in the heat dissipation bulk 208b and the LED chip 212 disposed on the heat dissipation bulk 208b.

On the other hand, the reflective layer 204b is only disposed between the LED chip 212 and the surface of the metal bulk 202b. The reflective layer 204b between the LED chip 212 and the metal bulk 202b can reflect the light emitted by the LED chip 212 towards the heat dissipation bulk 208b. In another embodiment, when the material of the metal bulk 202b is a highly reflective metal, the reflective layer 204b can be omitted. That is, the LED chip 212 is directly disposed on the surface of the metal bulk 202b.

Likewise, the material of the metal bulk 202b is preferably a high thermal conductivity material. In one embodiment, the material of the metal bulk 202b comprises, for example, Cu, Cu alloy, Fe/Ni alloy, Ni, W, Mo or any combination thereof. The material of the reflective layer 204b may be, for example, a stack structure of Ag/Au. The ceramic layer 206b may be preferably a transparent material, e.g. Al₂O₃.

The LED device of the present invention is also applicable to an LED chip of a vertical conductive type. FIG. 4 is a sectional view of an LED device according to yet another embodiment of the present invention. In this embodiment, the LED device 300 mainly includes a heat dissipation bulk 308, at least one LED chip 312 and at least one electrode pad 328. The LED chip 312 is disposed on the heat dissipation bulk 308, and the electrode pad 328 is embedded into the heat dissipation bulk 308.

The heat dissipation bulk 308 may be provided with one or more concaves for the electrode pads to be disposed therein. The number of the concaves of the heat dissipation bulk 308 is the same as that of the electrode pads of the LED device 300. Therefore, in the embodiment of FIG. 4, the heat dissipation bulk 308 may include one concave 310 for accommodating the electrode pad 328.

In one embodiment, as shown in FIG. 4, the heat dissipation bulk 308, for example, may include a metal bulk 302, a reflective layer 304 and a ceramic layer 306. The ceramic layer 306 covers a bottom surface 336 and an inner side surface 338 of the concave 310. The electrode pad 328 is disposed inside the ceramic layer 306 in the concave 310. Since the ceramic layer 306 has the insulating characteristic, the ceramic layer 306 can electrically isolate the electrode pad 328 in the heat dissipation bulk 308 and the LED chip 312 disposed on the heat dissipation bulk 308.

The reflective layer 304 may be disposed between the LED chip 312 and a surface of the metal bulk 302 only. Since the reflective layer 304 is between the LED chip 312 and the metal bulk 302, the reflective layer 304 can reflect the light emitted by the LED chip 312 towards the heat dissipation bulk 308. In another embodiment, when the material of the metal bulk 302 is a highly reflective metal, the reflective layer 304 can be omitted. That is, the LED chip 312 is directly disposed on the surface of the metal bulk 302.

The material of the metal bulk 302 is preferably a high thermal conductivity material. In one embodiment, the material of the metal bulk 302 comprises, for example, Cu, Cu alloy, Fe/Ni alloy, Ni, W, Mo or any combination thereof. The material of the reflective layer 304 may be, for example, a stack structure of Ag/Au. The ceramic layer 306 may be preferably a transparent material, e.g. Al₂O₃.

In this embodiment, the LED chip 312 is of the vertical conductive type. The LED chip 312 mainly includes a substrate 314, a first conductivity type semiconductor layer 316, an active layer 318, a second conductivity type semiconductor layer 320, a first electrode 322 and a second electrode 324. The first conductivity type semiconductor layer 316 and the second conductivity type semiconductor layer 320 are of different conductivity types. For example, one of the first conductivity type semiconductor layer 316 and the second conductivity type semiconductor layer 320 is n-type, and the other is p-type. Furthermore, the first electrode 322 and the first conductivity type semiconductor layer 316 are of the same conductivity type, and the second electrode 324 and the second conductivity type semiconductor layer 320 are of the same conductivity type.

The substrate 314 may be preferably a transparent conductive substrate. The first conductivity type semiconductor layer 316 is stacked on the substrate 314. The active layer 318 is stacked on the first conductivity type semiconductor layer 316. The second conductivity type semiconductor layer 320 is stacked on the active layer 318. The first electrode 322 is disposed on a surface of the substrate 314. The first electrode 322 and the first conductivity type semiconductor layer 316 are respectively disposed on two opposite sides of the substrate 314. The second electrode 324 is disposed on a part of the second conductivity type semiconductor layer 320. The second electrode 224 may be at least electrically connected to the electrode pad 328 through a bonding wire 326. The electrode pad 328 may be connected to an external power source through a bonding wire 330. On the other hand, since the first electrode 322 directly contacts the reflective layer 304 or directly contacts the metal bulk 302, the first electrode 322 and the heat dissipation bulk 308 are electrically connected. Therefore, in the packaging process of the LED device 300, the metal bulk 302 of the heat dissipation bulk 308 may be bonded to a conductive lead frame for packaging (not shown). As a result, an external power source may supply power to the LED chip 312 by means of the conductive lead frame and directly through the metal bulk 302 or through the metal bulk 302 and the reflective layer 304.

In one embodiment, the LED device 300 may only include a single LED chip 312. In another embodiment, the LED device 300 may include multiple LED chips 312. In this embodiment, each LED chip 312 may be used in combination with a single electrode pad. Therefore, the number of the electrode pads may be adjusted in accordance with the number of the LED chips 312 of the LED device 300.

As shown in FIG. 4, the first electrode 322 and a part of the substrate 314 of the LED chip 312 are embedded into the heat dissipation bulk 308. In this embodiment, a depth 334 of the LED chip 312 embedded into the heat dissipation bulk 308 is controlled to prevent the light emitted by the active layer 318 of the LED chip 312 towards the heat dissipation bulk 308 from being excessively confined by the heat dissipation bulk 308. In an embodiment, the depth 334 of the LED chip 312 embedded into the heat dissipation bulk 308 may be between 6 μm and 10 μm.

In a preferred embodiment, the ratio of the thickness 332 of the LED chip 312 to the depth 334 of the LED chip 312 embedded into the heat dissipation bulk 308 may be, for example, between 10 and 15.

In an embodiment, as shown in FIG. 4, the electrode pad 328 may be completely embedded into the concave 310. In another embodiment, the electrode pad 328 may be partially embedded into the concave 310, and partially protrude from the heat dissipation bulk 308. In this embodiment, the part of the electrode pad 328 protruding from the heat dissipation bulk 308 is preferably lower than the active layer 318 of the LED chip 312. The height of the electrode pad 328 protruding from the heat dissipation bulk 308 may be, for example, between 0 μm and 100 μm.

It can be seen from the above embodiments that an advantage of the present invention lies in that the electrode pad of the LED device of the present invention may be partially or completely embedded into the heat dissipation bulk. As a result, the influence of the electrode pad on the side light emitted by the LED chip can be avoided or reduced. Therefore, the overall luminance of the LED device can be effectively improved.

It can be seen from the above embodiments that another advantage of the present invention lies in that the LED chip of the LED device of the present invention is partially embedded into the heat dissipation bulk, so that the heat generated by the LED chip in operation can be directly conducted downwards to the heat dissipation bulk, thus rapidly dissipating the heat generated in operation. Therefore, the operating quality of the LED device can be improved and the service life of the LED device can be extended.

It can be seen from the above embodiments that yet another advantage of the present invention lies in that the depth of the LED chip embedded into the heat dissipation bulk according to the LED device of the present invention is controlled, so that the light emitted by the LED chip towards the substrate can be reflected by the heat dissipation bulk to the outside of the LED device through the light transmissive substrate. Therefore, the overall luminance of the LED device can be further improved.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) device, comprising:
a heat dissipation bulk with at least two concaves;
a first electrode pad and a second electrode pad, respectively disposed in the concaves and electrically isolated from each other; and
at least one LED chip, embedded into the heat dissipation bulk, wherein the heat dissipation bulk electrically isolates the LED chip, the first electrode pad and the second electrode pad, and wherein the LED chip comprises a first electrode and a second electrode of different conductivity types, and the first electrode and the second electrode are electrically connected to the first electrode pad and the second electrode pad respectively.

2. The LED device according to claim 1, wherein the heat dissipation bulk comprises:
a metal bulk; and
a ceramic layer, disposed on the metal bulk, electrically isolating the first electrode pad, the second electrode pad and the LED chip.

3. The LED device according to claim 2, wherein the heat dissipation bulk further comprises a reflective layer disposed between the metal bulk and the LED chip.

4. The LED device according to claim 2, wherein the ceramic layer is a transparent material.

5. The LED device according to claim 2, wherein the ceramic layer conformally covers a surface of the metal bulk.

6. The LED device according to claim 5, wherein the heat dissipation bulk further comprises a reflective layer conformally covering the surface of the metal bulk and disposed between the metal bulk and the ceramic layer.

7. The LED device according to claim 2, wherein the ceramic layer covers an inner side surface and a bottom surface of each of the concaves.

8. The LED device according to claim 1, wherein the LED chip comprises an active layer, and the first electrode pad and the second electrode pad both partially protrude from the heat dissipation bulk and are both lower than the active layer.

9. The LED device according to claim 1, wherein the first electrode pad and the second electrode pad are both completely embedded into the concaves.

10. The LED device according to claim 1, wherein a depth of the LED chip embedded into the heat dissipation bulk is between 6 μm to 10 μm.

11. The LED device according to claim 1, wherein a ratio of a thickness of the LED chip to a depth of the LED chip embedded into the heat dissipation bulk is between 10 and 15.

12. A light-emitting diode (LED) device, comprising:
a heat dissipation bulk with at least one concave;
at least one electrode pad, disposed in the concave; and
at least one LED chip, embedded into the heat dissipation bulk, wherein the heat dissipation bulk electrically isolates the LED chip and the electrode pad, and wherein the LED chip comprises:
a first electrode, embedded into the heat dissipation bulk; and
a second electrode, disposed on the other side of the LED chip opposite to the first electrode, wherein the second electrode is electrically connected to the electrode pad through at least one bonding wire, and the first electrode and the heat dissipation bulk are electrically connected.

13. The LED device according to claim 12, wherein the heat dissipation bulk comprises:
a metal bulk; and
a ceramic layer, disposed on the metal bulk, and electrically isolating the electrode pad and the LED chip.

14. The LED device according to claim 13, wherein the heat dissipation bulk further comprises a reflective layer disposed between the metal bulk and the LED chip.

15. The LED device according to claim 13, wherein the ceramic layer is a transparent material.

16. The LED device according to claim 13, wherein the ceramic layer covers an inner side surface and a bottom surface of the concave.

17. The LED device according to claim 12, wherein the LED chip comprises an active layer, and the electrode pad partially protrudes from the heat dissipation bulk and is lower than the active layer.

18. The LED device according to claim 12, wherein the electrode pad is completely embedded into the concave.

19. The LED device according to claim 12, wherein a depth of the LED chip embedded into the heat dissipation bulk is between 6 μm to 10 μm.

20. The LED device according to claim 12, wherein a ratio of a thickness of the LED chip to a depth of the LED chip embedded into the heat dissipation bulk is between 10 and 15.
